(19) United States
(12) Patent Application Publication
(10) Pub. No.: US 2012/0105090 A1
(43) Pub. Date: May 3, 2012

(54) PROBE DEVICE FOR TESTING

(75) Inventor: Chae Yoon Lee, Busan (KR)

(73) Assignee: LEENO INDUSTRIAL INC., Busan (KR)

(21) Appl. No.: 13/382,089

(22) PCT Filed: Jul. 29, 2009
(86) PCT No.: PCT/KR09/04206

§ 371 Date: Jan. 3, 2012

(30) Foreign Application Priority Data
Jul. 3, 2009 (KR) 10-2009-0060509

(51) Int. Cl. G01R 1/067

(52) U.S. Cl. 324/755.05; 324/755.04

(57) ABSTRACT

The present invention relates to a probe device for testing a semiconductor chip, and has the aim of providing a probe device for testing with higher test reliability through an improved structure that enables test current to flow safely, the probe device including a barrel open at the top and bottom thereof and a probe projection formed on a top end to contact a connection terminal of a semiconductor chip, an upper plunger having a lower portion housed in an upper portion of the barrel, and a lower plunger having an upper portion housed in a lower portion of the barrel, wherein a metal ball contained in cylindrical silicon to form a conductive silicon portion that exhibits conductivity and housed inside the band electrically connects the upper plunger and the lower plunger and resiliently supports the downward pressure transferred to the upper plunger during the testing of a semiconductor chip, such that the conductive silicon portion containing the metal ball for exhibiting conductivity and inserted in the barrel resiliently supports the upper plunger during a testing process, thus enabling a test current to flow safely along the conductive silicon portion and improving test reliability.

### BACKGROUND OF THE INVENTION

1. Field of the Invention

The present invention relates to a testing probe, and more particularly to a testing probe capable of enhancing test reliability using a conductive silicon section through which a stable test current flows.

2. Description of the Prior Art

Chips are integrated circuits that perform a variety of functions using logic elements fabricated on a thin small piece of semiconducting material. Such functions are activated by electrical signals transmitted from a printed circuit board (PCB) through buses.

In general, a lot of chips are mounted in a variety of electronic products, and play an important role in determining the performance of each electronic product.

Further, the PCB is constructed so that a conductor, copper, is coated to form circuit wiring on a thin board made of an insulator, such as epoxy resin or bakelite resin. The PCB has electric/electronic elements such as integrated circuits, resistors, and switches soldered on the circuit wiring.

Microchips refer to chips in which the electronic circuit of the PCB is integrated at high density. In order to check whether or not such a chip is normal before the chip is mounted on and assembled with any electronic product, the chip must be tested using test equipment.

In this testing method, the chip is mounted on a testing socket. In order to test the chip in the testing socket without damaging it, a testing probe is mounted and used.

The testing socket is generally mounted on a testing PCB, and the microchip to be tested is placed on the testing socket. Then, the test is performed. The testing socket is mounted with a plurality of testing probes.

FIG. 1 is a cross-sectional view illustrating a conventional testing probe.

As illustrated in FIG. 1, the testing probe includes a barrel 20, an upper plunger 10 having a testing probe projection 12 slidably installed in the barrel 20, and a lower plunger 40 installed at a lower end of the barrel. A coil spring 30 is installed in the barrel 20, and elastically supports the upper plunger 10.

When a microchip is tested using this construction, the microchip is placed on a testing socket, and is pressed downward using a pressing unit installed on the testing socket. Thereby, the microchip comes into contact with the probe projection of the upper plunger.

FIG. 2 illustrates the state in which a current flows through the testing probe of FIG. 1.

As illustrated in FIG. 2, the probe projection 12 comes into contact with the connection terminal 2 of a semiconductor chip 1, test current flows to a body of the upper plunger 10, and then to the electrode pad 4 of a testing PCB 3 through a body of the barrel 20 and the lower plunger 40. Part of the current flowing through an inner wall of the barrel 20 flows to the lower plunger 40 through the coil spring 30.

Thus, the current of the testing PCB flows to separately provided test equipment (not shown) through the testing probe. In this process, it is possible to test normal operation of the semiconductor chip.

Reliability tests using the testing probe are dependent upon a smooth flow of the current flowing through the testing probe. Although the coil spring 30 is compressed, the coil spring 30 comes into contact with the inner wall of the barrel 20 only within a specific area A, and thus the current flowing to the lower plunger through the coil spring 30 is attributed to an unstable response characteristic of the test current in the testing process.

### DETAILED DESCRIPTION OF THE INVENTION

### Technical Problems

Accordingly, embodiments of the present invention are directed towards providing a testing probe capable of enhancing test reliability by modifying a structure so as to allow stable test current to flow.

### Technical Solutions

According to an aspect of the present invention, there is provided a testing probe, which includes: a barrel, opposite ends of which are open; an upper plunger, at an upper end of which a probe projection is formed so as to be in contact with a connection terminal of a semiconductor chip, and a lower portion of which is held in an upper portion of the barrel; and a lower plunger, an upper portion of which is held in a lower portion of the barrel. The barrel receives a conductive silicon section having conductivity due to metal powder contained in a silicon cylinder, and the conductive silicon section electrically connects the upper plunger and the lower plunger, and elastically supports downward pressure transmitted to the upper plunger during testing each semi-conductor chip.

Here, the barrel may include a coil spring installed therein so as to elastically support the upper plunger.

Further, the coil spring may have an inner diameter larger than an outer diameter of the conductive silicon section by a range from 0.02 mm to 0.2 mm.

According to another aspect of the present invention, there is provided a testing probe for testing semiconductor chips. The testing probe includes: an upper plunger, at an upper end of which a probe projection is formed so as to be in contact with a connection terminal of a semiconductor chip; a barrel, having open opposite ends and holding a lower portion of the upper plunger 10 in an upper portion thereof; a lower plunger, an upper portion of which is held in a lower portion of the barrel; a coil spring elastically supporting the upper plunger held in the barrel; and a conductive silicon section held in the coil spring and having conductivity due to metal powder contained in a silicon cylinder. When coming into contact with the semi-conductor chip, the upper plunger is primarily and elastically supported by the coil spring and is secondarily and elastically supported by the conductive silicon section.

### Advantageous Effects

According to embodiments of the present invention, the conductive silicon section, in which metal powder is contained to impart conductivity, can be held in the barrel, and elastically support the upper plunger during testing, and stable test current can flow along the conductive silicon section, so that the testing probe can enhance test reliability.

### BRIEF DESCRIPTION OF THE DRAWINGS

FIG. 1 is a cross-sectional view illustrating a conventional testing probe.

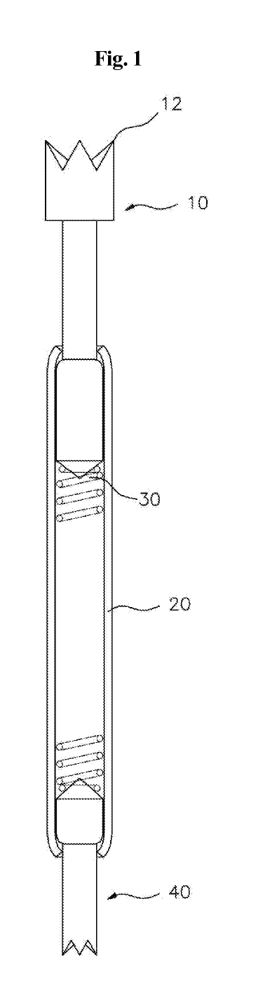

FIG. 2 illustrates the state in which a current flows through the testing probe of FIG. 1.

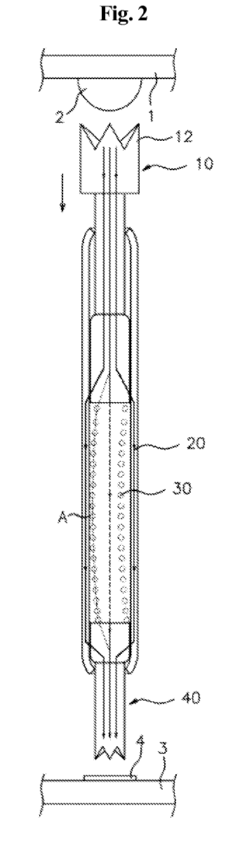

FIGS. 3A and 3B are cross-sectional views illustrating a testing probe according to an exemplary embodiment of the present invention.

FIG. 4 is a cross-sectional view illustrating a testing probe according to another exemplary embodiment of the present invention.

FIG. 5 is a cross-sectional view illustrating a testing probe according to another exemplary embodiment of the present invention.

FIG. 6 illustrates the state in which current flows through the testing probe of FIG. 5.

### BEST MODES FOR CARRYING OUT THE INVENTION

Reference will now be made in greater detail to a testing probe according to exemplary embodiments of the present invention with reference to the accompanying drawings.

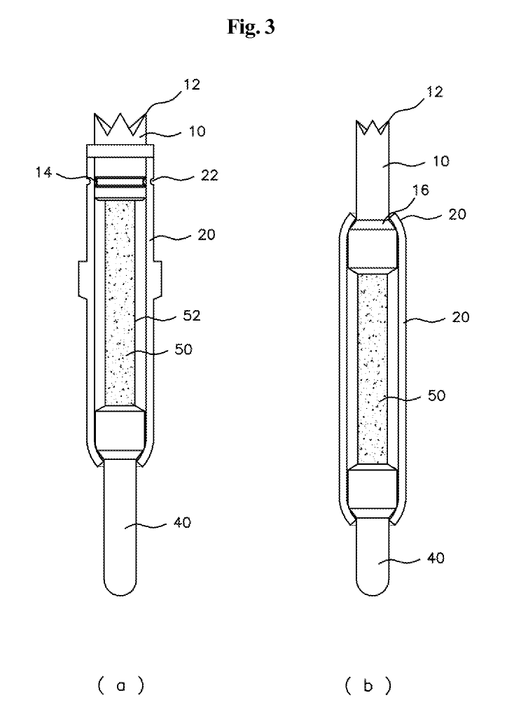

FIGS. 3A and 3B are cross-sectional views illustrating a testing probe according to an exemplary embodiment of the present invention.

As illustrated in FIGS. 3A and 3B, the testing probe includes an upper plunger 10, at an upper end of which a probe projection 12 is formed so as to be in contact with the connection terminal of a semiconductor chip, a barrel 20 having open opposite ends and holding a lower portion of the upper plunger 10 in an upper portion thereof, a lower plunger 40, an upper portion of which is held in a lower portion of the barrel 20, and a conductive silicon section 50 having conductivity due to metal powder contained in a silicon cylinder held in the barrel 20.

First, in the embodiment illustrated in FIG. 3A, the upper plunger 10 is fixed to the barrel 20 in such a manner that a pressure ridge 22 formed on the upper portion of the barrel 20 is fitted into a trough 14 formed in the lower portion of the upper plunger 10. In the embodiment illustrated in FIG. 3B, the upper plunger 10 is fixed to the barrel 20 so as to be movable in a vertical direction in such a manner that a step 16 formed on the lower portion of the upper plunger 10 is restricted on an inwardly bent catch 24 formed at an upper end of the barrel 20.

The conductive silicon section 50 is formed of silicon having elasticity and metal powder having conductivity in a cylindrical shape, and thus has elasticity and conductivity.

Accordingly, in the process of testing semiconductor chips, vertical force transmitted through the probe projection 12 is elastically supported by the conductive silicon section 50, and test current applied to the probe projection 12 is conducted to the lower plunger 40 through the conductive silicon section 50.

Next, the testing probe according to another exemplary embodiment of the present invention will be described.

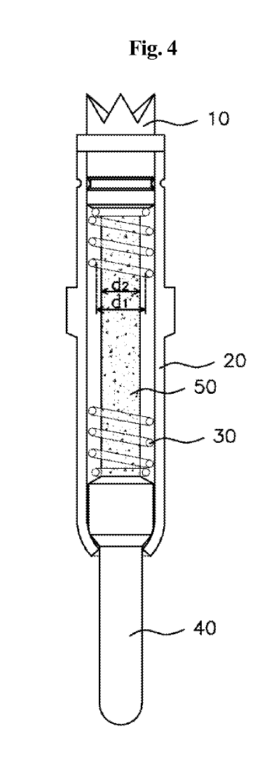

FIG. 4 is a cross-sectional view illustrating a testing probe according to another exemplary embodiment of the present invention.

The embodiment illustrated in FIG. 4 has a construction that adds a coil spring 30 to the embodiment illustrated in FIG. 4.

The coil spring 30 is mounted in the barrel 20 so as to elastically support the upper plunger 10. A difference (d2 minus d1) between an inner diameter d1 of the coil spring 30 and an outer diameter d2 of the conductive silicon section 50 may be limited to a range from 0.02 mm to 0.2 mm.

In general, the coil spring used for the testing probe is manufactured using a wire having a diameter between 0.02 mm and 0.20 mm. At this time, the coil spring has an inner diameter between 0.2 mm and 2.0 mm according to a target to be tested.

The conductive silicon section 50 is deformed in a radial outward direction during compression, and thus may come into contact with an inner diameter region of the coil spring 30. As such, the conductive silicon section 50 must be spaced apart from the coil spring 30 by a predetermined interval within the aforementioned dimensional range, so that the conductive silicon section 50 and the coil spring 30 can normally and elastically support the upper plunger 10.

Next, the testing probe according to another exemplary embodiment of the present invention will be described.

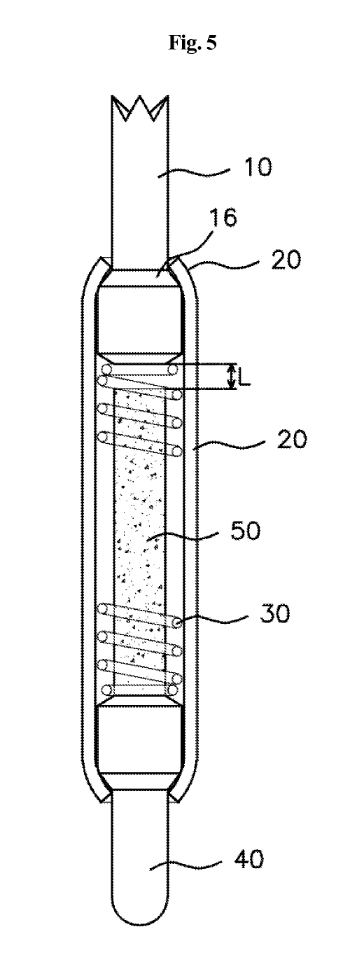

FIG. 5 is a cross-sectional view illustrating a testing probe according to another exemplary embodiment of the present invention.

*The embodiment illustrated in FIG. 5 is constructed so that an upper plunger 10 is primarily and elastically supported by a coil spring 30 and is secondarily and elastically supported by a conductive silicon section 50.

Thus, in the normal state, the conductive silicon section 50 is spaced apart from the upper plunger 10 by a predetermined distance L without contact with the bottom of the upper plunger 10.

In the process of testing the semiconductor chip, the upper plunger 10 is supported by the coil spring 30 in the initial stage. Then, after the upper plunger 30 is shifted by the predetermined distance L, the conductive silicon section 50 elastically supports the upper plunger 10 while coming into contact with the bottom of the upper plunger 10. Of course, the coil spring 30 elastically support the upper plunger 10 as well.

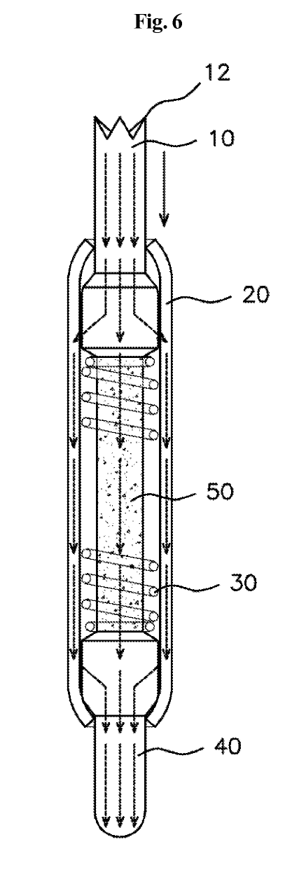

FIG. 6 illustrates the state in which current flows through the testing probe of FIG. 5.

As illustrated in FIG. 6, when a semiconductor chip comes into contact with the probe projection 12 of the upper plunger 10, the upper plunger 10 moves in a vertical downward direction, so that the coil spring 30 and the conductive silicon section 50 are compressed. Thus, the test current flows from the upper plunger 10 to the lower plunger 40 through at least one of the barrel 20, the coil spring 30, and the conductive silicon section 50, so that a response characteristic of the test current can be improved compared to a conventional testing probe.

Although a testing probe in which a conductive silicon section is accommodated in a barrel according to exemplary embodiments of the invention have been described for illustrative purposes, those skilled in the art will appreciate that various modifications, additions and substitutions are possible, without departing from the scope and spirit of the invention as disclosed in the accompanying claims.

### INDUSTRIAL APPLICABILITY

The present invention is applicable to a testing probe, and more particularly to a testing probe capable of enhancing test reliability using a conductive silicon section through which a stable test current flows.

What is claimed is:

1. A testing probe for testing semiconductor chips, comprising:
a barrel, opposite ends of which are open;
an upper plunger, at an upper end of which a probe projection is formed so as to be in contact with a connection terminal of a semiconductor chip, and a lower portion of which is held in an upper portion of the barrel; and
a lower plunger, an upper portion of which is held in a lower portion of the barrel,
wherein the barrel receives a conductive silicon section having conductivity due to metal powder contained in a silicon cylinder, and the conductive silicon section electrically connects the upper plunger and the lower plunger, and elastically supports downward pressure transmitted to the upper plunger during testing each semi-conductor chip.

2. The testing probe as set forth in claim 1, wherein the barrel includes a coil spring installed therein so as to elastically support the upper plunger.

3. The testing probe as set forth in claim 2, wherein the coil spring has an inner diameter larger than an outer diameter of the conductive silicon section by a range from 0.02 mm to 0.2 mm.

4. A testing probe for testing semiconductor chips, comprising:
an upper plunger, at an upper end of which a probe projection is formed so as to be in contact with a connection terminal of a semiconductor chip;
a barrel, having open opposite ends and holding a lower portion of the upper plunger 10 in an upper portion thereof;
a lower plunger, an upper portion of which is held in a lower portion of the barrel;
a coil spring elastically supporting the upper plunger held in the barrel; and
a conductive silicon section held in the coil spring and having conductivity due to metal powder contained in a silicon cylinder,
wherein, when coming into contact with the semi-conductor chip, the upper plunger is primarily and elastically supported by the coil spring and is secondarily and elastically supported by the conductive silicon section.
